(19) United States
(12) Patent Application Publication
(10) Pub. No.: US 2001/0055198 A1
(43) Pub. Date: Dec. 27, 2001

(54) Heat sink

(75) Inventor: Woang Sik Park, Suwon-Shi (KR)

Correspondence Address: DARBY & DARBY P.C., 805 Third Avenue, New York, NY, 10022, US

(73) Assignee: SAMSUNG ELECTRO-MECHANICS CO., LTD., SUWON-SHI, KYUNGKI-DO (KR)

(21) Appl. No.: 09/812,797

(22) Filed: Mar. 20, 2001

(30) Foreign Application Priority Data
Jun. 24, 2000 (KR) 2000-35051

(51) Int. Cl. H05K 7/20

(52) U.S. Cl. 361/700

(57) ABSTRACT

Disclosed is a heat sink including a body being in contact with a heat emitting surface of an integrated circuit package serving as a heat emitting body, heat discharge fins integrally formed with the body and adapted to discharge heat transmitted thereto, shafts integrally formed with the body so that they are protruded from a surface of the body facing the heat emitting surface, each of the shafts extending through an associated one of through holes formed at a printed circuit board to which the integrated circuit package is mounted, compression coil springs each fitted around a protruded portion of the associated shaft, each compression coil spring serving to apply an elastic support force to the printed circuit board, and retaining means adapted to enlarge the protruded portion of the associated shaft, thereby preventing the associated coil spring from being separated from the associated shaft. Since the shafts are firmly retained by the ring members, the heat sink can be easily assembled and disassembled with respect to the printed circuit board. Accordingly, an improvement in workability is achieved. A uniform pressure is applied between the heat emitting surface of the integrated circuit package and the body of the heat sink, so that it is possible to stably maintain a desired heat discharge effect of the heat sink.

### BACKGROUND OF THE INVENTION

1. Field of the Invention

The present invention relates to a heat sink for providing heat discharge characteristics for integrated circuit packages, such as semiconductors, from which a large quantity of heat is generated. In particular, the present invention relates to a heat sink which can be firmly mounted to the heat emitting surface of an integrated circuit package.

2. Description of the Prior Art

Electronic chips, such as central processing units (CPUs) of computers, which have recently been developed to achieve an ultra miniature, a high processing speed, and a high capacity, involve an increase in the quantity of heat generated therefrom. Due to the miniature and high density made in electronic products, simultaneously with an improvement in performance, however, the conditions for removing heat generated has been rendered to be more severe.

The quantity of heat generated from integrated circuit packages (hereinafter, those integrated circuit packages is referred to as CPUs) has been continuously increased in proportion to the increase in the performance of computers. For instance, although heat of 8 W or less is generated from CPUs of a 486 grade, for example, 66 MHz, developed at the past, heat of 16 to 35 W is typically generated from CPUs of a 1,000 MHz grade. In the case of CPUs of a GHz grade, it is expected that heat of 50 W or more is generated.

Meanwhile, the current tendency associated with computers is to reduce the size. This tendency causes the thermal conditions of CPUs to be severe. For this reason, it is important to effectively dischage heat generated from CPUs in order to obtain a desired reliability and performance in the case of products having a high capacity.

In particular, CPUs involve a problem of hot spots because they are under a high temperature condition, as compared to other elements.

That is, the condition, in which CPUs are heated to a high temperature, results in a degradation in clock speed, an erroneous operation, and an great increase in the error generation rate. It has been reported that an increase in the error generation rate up to 5.2 times occurs when the temperature of a CPU increases by 50° C.

For this reason, active research has been made to develope means for effectively discharging heat generated from a CPU mounted to a computer, in pace with research of CPUs with a high density. For such means for discharging heat generated from a CPU, a cooling device has been developed which includes a heat sink and a heat discharge fan.

In such a cooling device, which includes a heat sink and a heat discharge fan, the heat sink is typically made of a material exhibiting a superior thermal conductivity. In particular, the heat sink has a heat discharge structure for rapidly discharging heat transferred from an electronic chip thereto.

The heat discharge fan is arranged at one side of the heat sink, and has a structure capable of improving the heat discharge characteristics of the heat sink.

FIG. 1 is a sectional view illustrating a conventional heat sink in a clamped state. As shown in FIG. 1, the conventional heat sink, which is denoted by the reference numeral 100, is mounted to a printed circuit board 120 by means of clampers 130 in a state in which it is disposed on an integrated circuit package 110 mounted on the printed circuit board 120.

The heat sink 100 includes a body 101 contacting the upper surface of the integrated circuit package 110, that is, a heat emitting surface, and a plurality of heat discharge fins 105 adapted to discharge heat transferred to the body 101 into the atmosphere. The clampers 130, which are also included in the heat sink 100, serve to maintain the body 101 to be firmly in contact with the integrated circuit package 110.

The body 101 of the heat sink has a flat lower surface contating the upper surface of the integrated circuit package 110, so that it receives heat transferred from the integrated circuit package 110.

The heat discharge fins 105 are arranged on the upper surface of the body 101 in such a fashion that they are uniformly spaced from one another while extending vertically from the upper surface of the body 101. The heat discharge fins 105 serve to rapidly discharge heat transferred thereto into the atmosphere in accordance with a forced or natural convection.

The heat sink 100 is provided with a plurality of through holes 102. In similar, the printed circuit board 120 has a plurality of through holes 121 respectively corresponding to the through holes 102 of the heat sink 100. As shown in FIG. 2, the clampers 130 are inserted into the through holes 102 and 121 in a state in which associated ones of those through holes 102 and 121 are aligned with each other. In the inserted state, the clampers 130 are engaged with the lower surface of the printed circuit board 120, so that it serves to fix the heat sink 100 to the printed circuit board 120.

Each of the dampers 130 mainly includes a shaft 131 and a compression coil spring 135. In particular, the shaft 131 of each damper 130 is provided at its upper end with a head having a diameter larger than those of the through holes 102 and 121, and at its lower end with an conical engagement portion 132. The conical engagement portion 132 is slitted into two lateral portions by a central slit 133 so that it can be elastically reduced or increased in width. By virtue of such a structure, the conical engagement portion 132 can be allowed to be inserted through the through holes 102 and 121 by virtue of its width reduction, and then to be engaged with the lower surface of the printed circuit board 120 after the insertion by virtue of its width increase.

After the insertion of the shaft 131 included in each damper 130 through the associated through holes 102 and 121 of the body 101 and printed circuit board 120, the end surface of the engagement portion 132 included in the shaft 131 comes into contact with the peripheral edge of the through hole 121 of the printed circuit board 120 as it expands diametrically, so that the shaft 121 is prevented from being seperated in a direction reverse to the insertion direction. The coil spring 135 of each clamper 130 serves to exert an elastic urging force in a direction in which the engagement portion 132 of the shaft 131 and the body 101 of the heat sink 100 are spaced away from each other. By virtue of this structure, the heat sink 100 is in close contact with the integrated circuit package 110.

In the conventional heat sink having the above mentioned configuration, however, it is difficult to separate the shaft 131 of each clamper 130 from the printed circuit board 120. Furthermore, the printed circuit board 120 or integrated circuit package 110 may be damaged during the assembling or disassembling process.

That is, there is a degradation in workability in the separation of the shaft 131 from the printed circuit board 120 in that the engagement portion 132 of the shaft 131 should be pushed in an upward direction, that is, toward the heat sink 100, in a state in which the engagement portion 132 is forcibly reduced in width, in order to allow the shaft 131 to be separated from the printed circuit board 120. Furthermore, where the shaft 131 is repeatedly subjected to the assembling and disassembling processes, its engagement portion 132 made of a synthetic resin material may be permanently deformed, thereby resulting in a degradation in the elastic strain thereof. As a result, it is difficult for the engagement portion 132 of the shaft 131 to perform its function.

Meanwhile, the engagement portion 132 of the shaft 131 can exert a desired engagement force only when it is completely protruded from the associated through hole 121 of the printed circuit board 120. To this end, the user should strongly push the shaft 131 against the printed circuit board 120 in a downward direction. Due to this force, the printed circuit board 120 and integrated circuit package 110 may be damaged.

### SUMMARY OF THE INVENTION

Therefore, an object of the invention is to provide a heat sink having a configuration capable of allowing the heat sink to be conveniently coupled to and separated from a printed circuit board to which an integrated circuit package is mounted.

Another object of the invention is to provide a heat sink having a configuration capable of stably maintaining the heat sink to be in close contact with an integrated circuit package, thereby achieving a uniform heat discharge effect.

In accordance with one aspect, the present invention provides a heat sink comprising: a body adapted to be in contact with a heat emitting surface of an integrated circuit package serving as a heat emitting body; a plurality of heat discharge fins integrally formed with the body and adapted to discharge heat transmitted thereto; a plurality of shafts integrally formed with the body so that they are protruded from a surface of the body facing the heat emitting surface of the integrated circuit package, each of the shafts extending through an associated one of through holes formed at a printed circuit board to which the integrated circuit package is mounted; a plurality of compression coil springs each fitted around a portion of an associated one of the shafts protruded from an associated one of the through holes, each of the compression coil springs serving to apply an elastic support force to the printed circuit board; and a plurality of retaining means adapted to enlarge the protruded portion of an associated one of the shafts, thereby preventing an associated one of the coil springs from being separated from the associated shaft.

In this heat sink, each of the retaining means includes an annular groove formed around the protruded portion of an associated one of the shafts, and a ring member elastically fitted around the annular groove.

In accordance with another aspect, the present invention provides a heat sink comprising: a body adapted to be in contact with a heat emitting surface of an integrated circuit package serving as a heat emitting body, the body being provided with a plurality of through holes respectively corresponding to through holes formed at a printed circuit board to which the integrated circuit package is mounted; a plurality of heat discharge fins integrally formed with the body and adapted to discharge heat transmitted thereto; a plurality of shafts each having one end extending through associated ones of the through holes respectively formed at the body and the printed circuit board, each of the shafts also having, at the other end thereof, an enlarge portion having a diameter larger than those of the through holes; a plurality of compression coil springs each fitted around a portion of an associated one of the shafts protruded from the associated through holes, each of the compression coil springs serving to exert an elastic support force; and a plurality of retaining means adapted to enlarge the protruded portion of an associated one of the shafts, thereby preventing an associated one of the coil springs from being separated from the associated shaft.

In this heat sink, each of the retaining means includes an annular groove formed around the protruded portion of an associated one of the shafts, and a ring member elastically fitted around the annular groove.

### BRIEF DESCRIPTION OF THE DRAWINGS

The above objects, and other features and advantages of the present invention will become more apparent after a reading of the following detailed description when taken in conjunction with the drawings, in which:

FIG. 1 is a sectional view illustrating a conventional heat sink in a clamped state;

FIG. 2 is a perspective view illustrating the conventional heat sink;

FIG. 3 is a sectional view illustrating a heat sink according to an embodiment of the present invention;

FIG. 4 is an exploded perspective view illustrating an essential portion of the heat sink illustrated in FIG. 3;

FIG. 5 is a sectional view illustrating a heat sink according to another embodiment of the present invention; and

FIG. 6 is an exploded perspective view illustrating an essential portion of the heat sink illustrated in FIG. 5.

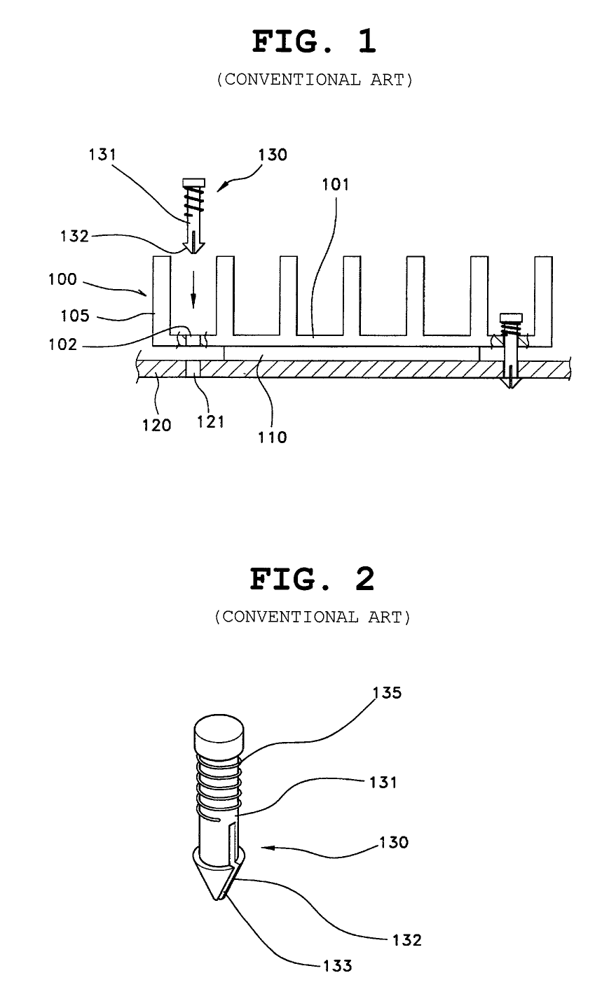

### DESCRIPTION OF THE PREFERRED EMBODIMENTS

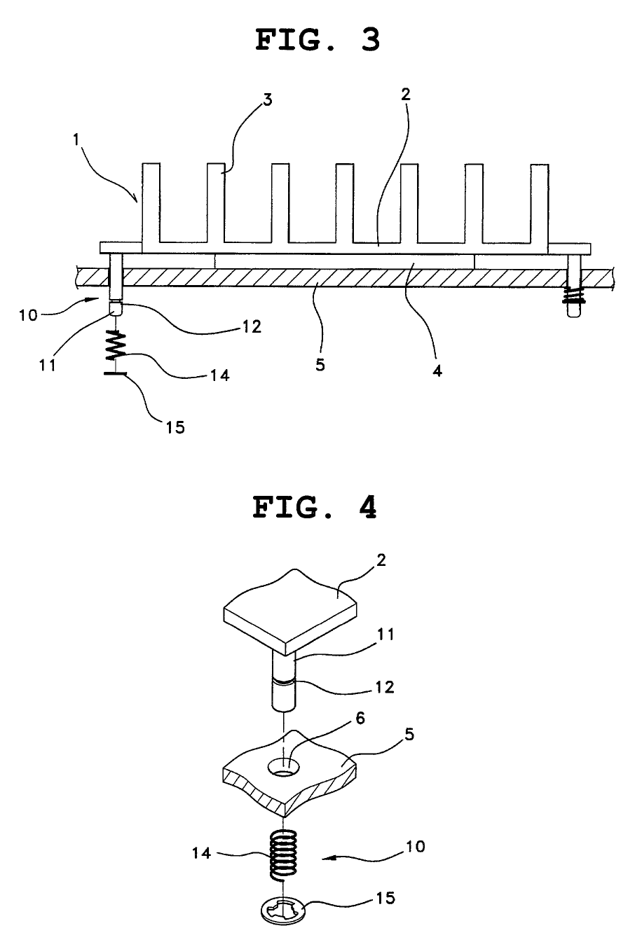

FIGS. 3 and 4 are a sectional view and an exploded perspective view illustrating a heat sink according to an embodiment of the present invention, respectively.

As shown in FIGS. 3 and 4, an integrated circuit package 4 such as a CPU is mounted to the main board of a computer, that is, a printed circuit board 5. A heat sink 1 is mounted to the printed circuit board 5 in a state in which it is in close contact with a heat emitting surface of the integrated circuit package 4.

The heat sink 1 includes a body 2 contacting the heat emitting surface of the integrated circuit package 4, a plurality of heat discharge fins 3 adapted to discharge heat transferred to the body 2 into the atmosphere, and a plurality of clampers 10 adapted to maintain the body 2 to be firmly in contact with the integrated circuit package 4.

When viewed in FIG. 3, the body 2 of the heat sink 1 has a flat lower surface contacting the heat emitting surface of the integrated circuit package 4, so that it receives heat transferred from the integrated circuit package 4.

The heat discharge fins 3 are arranged on the upper surface of the body 2 in such a fashion that they are uniformly spaced from one another while extending vertically from the upper surface of the body 2. The heat discharge fins 3 serve to rapidly discharge heat transferred thereto into the atmosphere in accordance with a forced or natural convection.

Each of the clampers 10 mainly includes a shaft 11, a compression coil spring 14, and a retaining means.

The shaft 11 of each clamper 10 has a column shape having a desired length. The shaft 11 extends vertically from the lower surface of the body 2 included in the heat sink 1.

Respective shafts 11 of the clampers 10 are formed integrally with the body 2 of the heat sink 2 at positions respectively corresponding to through holes formed at the printed circuit board 5 in accordance with an injection molding process. In an assembling process for the clampers 10, the tip of each shaft 11 is protruded through an associated one of the through holes 6 formed at the printed circuit board 5.

Preferably, each shaft 11 is formed to have a diameter smaller than that of the associated through hole 6 formed at the printed circuit board 5 so that it can be freely inserted into the through hole 6.

The compression coil spring 14 of each clamper 10 is an elastic member having a desired elastic force. This compression coil spring 14 is fitted around the protruded portion of the associated shaft 11 extending through the associated through hole 6 of the printed circuit board 5.

Each retaining means serves to prevent the associated coil spring 14 from the associated shaft 11 while limiting a movement of the shaft 11 along the associated through hole 6 of the printed circuit board 5. The retaining means includes an annular groove 12 formed at a portion of the shaft 11 near the tip of the shaft 11, and a ring member 15 fitted around the annular groove 12.

The annular groove 12 is formed to have a desired depth. The ring member 15 is elastically fitted around the annular groove 12. The ring member 15 also has an outer diameter larger than that of the associated compression coil spring 14 in order to stably prevent the compression coil spring 14 from being separated from the associated shaft 11. Typically, the ring member 15 comprises a well-known C-ring or O-ring.

In the assembling process for the heat sink 1, the body 2 of the heat sink 1 is first disposed on the integrated circuit package 4 in such a fashion that it is firmly in contact with the upper surface of the integrated circuit package 4, that is, the heat emitting surface, under the condition in which the integrated circuit package 4 is mounted to the printed circuit board 5.

In this state, each shaft 11 protruded from the lower surface of the body 2 included in the heat sink 1 extends through an associated one of the through holes 6 formed at the printed circuit board 5, so that its tip is protruded from the lower surface of the printed circuit board 5.

Thereafter, each coil spring 14 is fitted around the tip of the associated shaft 11 protruded from the associated through hole 6 of the printed circuit board 5. Each ring member 15 is then fitted around the annular groove 12 of the associated shaft 11. Thus, the process for clamping the heat sink 1 to the printed circuit board 5 is completed.

In the assembled state as mentioned above, the heat sink 1 and printed circuit board 5 are under the constant pressure toward the integrated circuit package 4 interposed therebetween because each compression coil spring 14 exerts an elastic expansion force between the printed circuit board 5 and the associated ring member 15.

As a result, the body 2 of the heat sink 1 comes into tight contact with the heat emitting surface of the integrated circuit package 4. Thus, a uniform heat discharge effect is obtained.

Meanwhile, each shaft 11 may be formed separately from the printed circuit board 5. In this case, the body 2 of the heat sink 1 is provided with a plurality of through holes 2a, as in the conventional case.

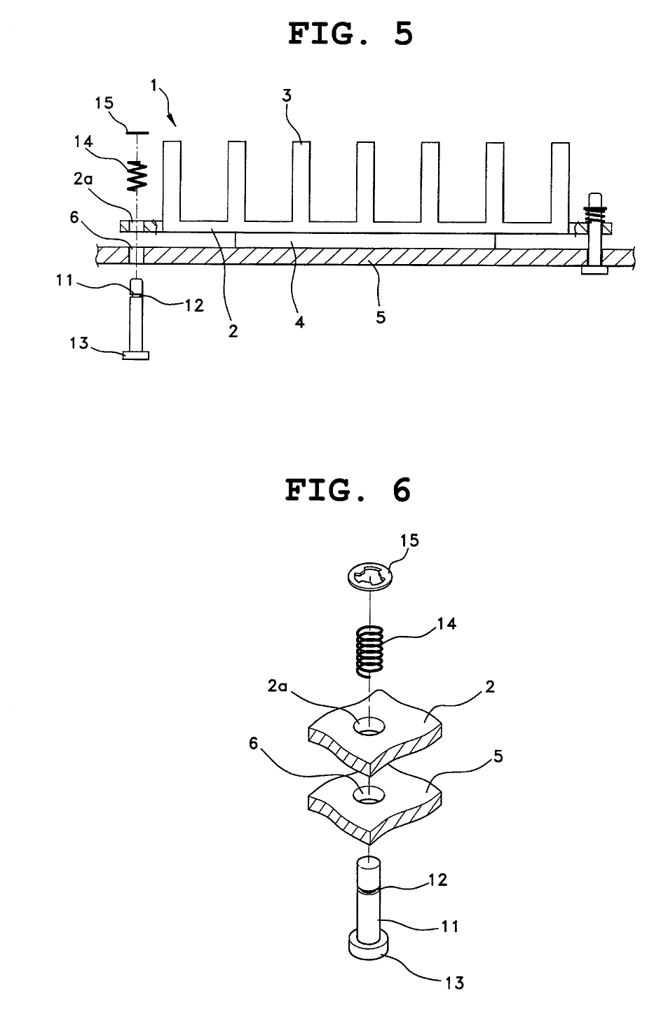

FIGS. 5 and 6 illustrate a heat sink according to another embodiment of the present invention. In FIGS. 5 and 6, elements respectively corresponding to those in FIGS. 3 and 4 are denoted by the same reference numerals. The heat sink 1 according to this embodiment has a feature in that each shaft 11 is provided, at an end thereof opposing to the annular groove 12, has an enlarged head 13 having a diameter larger than that of the associated through hole 6 formed at the printed circuit board 5, as compared to the embodiment illustrated in FIGS. 3 and 4.

In this heat sink 1, each shaft 11 is first inserted into the associated through hole 2a formed at the body 2, and then into the associated through hole 6 of the printed circuit board 5. Alternatively, each shaft 11 is first inserted into the associated through hole 6 of the printed circuit board 5, and then into the associated through hole 2a of the body 2. After the insertion of the each shaft 11, the associated coil spring 14 and ring member 15 are sequentially coupled to the protruded tip portion of the shaft 11. Thus, the assembling process of the heat sink 1 is completed.

When a disassembling process is carried out in the order reverse to that of the assembling process, the heat sink 1 is separated from the printed circuit board 5.

Since each compression coil spring 14 exerts an elastic expansion force between the printed circuit board 5 and the associated ring member 15, the heat sink 1 and printed circuit board 5 are under the constant pressure toward the integrated circuit package 4 interposed therebetween.

As a result, the body 2 of the heat sink 1 comes into tight contact with the heat emitting surface of the integrated circuit package 4. Thus, a uniform heat discharge effect is obtained.

In the case of the heat sink 1 according to either embodiment, the assembling process for the heat sink 1 to the printed circuit board 5 and the disassembling process for the heat sink 1 from the printed circuit board 5 can be easily carried out because each shaft 11 is firmly retained by the associated ring member. Accordingly, an improvement in workability is achieved.

In addition, a uniform pressure is applied between the heat emitting surface of the integrated circuit package and the body 2 of the heat sink 1. Accordingly, it is possible to stably maintain a desired heat discharge effect of the heat sink 1.

Thus, the heat sink 1 of the present invention exhibits a superior mountability and a superior workability, as compared to the conventional heat sink. It is also possible to minimize the damage applied to the integrated circuit package during the assembling process.

Accordingly, there is an advantage in that the rate of errors generated during the assembling process is considerably reduced. Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A heat sink comprising:
a body adapted to be in contact with a heat emitting surface of an integrated circuit package serving as a heat emitting body;
a plurality of heat discharge fins integrally formed with the body and adapted to discharge heat transmitted thereto;
a plurality of shafts integrally formed with the body so that they are protruded from a surface of the body facing the heat emitting surface of the integrated circuit package, each of the shafts extending through an associated one of through holes formed at a printed circuit board to which the integrated circuit package is mounted;
a plurality of compression coil springs each fitted around a portion of an associated one of the shafts protruded from an associated one of the through holes, each of the compression coil springs serving to apply an elastic support force to the printed circuit board; and
a plurality of retaining means adapted to enlarge the protruded portion of an associated one of the shafts, thereby preventing an associated one of the coil springs from being separated from the associated shaft.

2. The heat sink according to claim 1, wherein each of the retaining means includes an annular groove formed around the protruded portion of an associated one of the shafts, and a ring member elastically fitted around the annular groove.

3. A heat sink comprising:
a body adapted to be in contact with a heat emitting surface of an integrated circuit package serving as a heat emitting body, the body being provided with a plurality of through holes respectively corresponding to through holes formed at a printed circuit board to which the integrated circuit package is mounted;
a plurality of heat discharge fins integrally formed with the body and adapted to discharge heat transmitted thereto;
a plurality of shafts each having one end extending through associated ones of the through holes respectively formed at the body and the printed circuit board, each of the shafts also having, at the other end thereof, an enlarge portion having a diameter larger than those of the through holes;
a plurality of compression coil springs each fitted around a portion of an associated one of the shafts protruded from the associated through holes, each of the compression coil springs serving to exert an elastic support force; and
a plurality of retaining means adapted to enlarge the protruded portion of an associated one of the shafts, thereby preventing an associated one of the coil springs from being separated from the associated shaft.

4. The heat sink according to claim 3, wherein each of the retaining means includes an annular groove formed around the protruded portion of an associated one of the shafts, and a ring member elastically fitted around the annular groove.
